(19) United States
(12) Patent Application Publication
(10) Pub. No.: US 2025/0194165 A1
(43) Pub. Date: Jun. 12, 2025

(54) UNIFICATION OF BACKSIDE STRESS MITIGATION WITH FRONTSIDE PROTECTION IN SEMICONDUCTOR MANUFACTURING PROCESSING

(71) Applicant: Applied Materials, Inc., Santa Clara, CA (US)

(72) Inventors: Changwoo Sun, Dublin, CA (US); Pradeep Kumar Subrahmanyan, San Jose, CA (US); Li Qun Xia, Cupertino, CA (US)

(21) Appl. No.: 18/974,145

(22) Filed: Dec. 9, 2024

Related U.S. Application Data
(60) Provisional application No. 63/695,291, filed on Sep. 16, 2024.
(60) Provisional application No. 63/608,429, filed on Dec. 11, 2023.

(51) Int. Cl. H10D 30/69; H01L 21/02; H01L 21/3115; H01L 21/683

(52) U.S. Cl. CPC H10D 30/791; H01L 21/0217; H01L 21/31155; H01L 21/6831

(57) ABSTRACT

Disclosed systems and techniques are directed to optimization of semiconductor manufacturing by unifying back side and front side processing operations, including forming a plurality of features on a front side of a substrate and covering the features with a feature protection layer. The techniques further include forming a stress-compensation layer (SCL) on a back side of the substrate, the SCL causing reduction of deformation of the substrate, and removing, in a unified processing operation, the feature protection layer and a subplurality of the features.

### RELATED APPLICATIONS

This application claims the benefit of the U.S. Provisional Patent Application No. 63/608,429, filed Dec. 11, 2023, and U.S. Provisional Patent Application No. 63/695,291, filed Sep. 16, 2024, the contents of both applications being incorporated in their entirety by reference herein.

### TECHNICAL FIELD

The disclosure pertains to semiconductor manufacturing, including processing of substrates and devices manufactured thereon.

### BACKGROUND

Modern semiconducting devices, such as processing units, memory devices, light detectors, solar cells, light-emitting semiconductor devices, devices that deploy complementary metal-oxide-semiconductor (CMOS) structures, and the like, are often manufactured on silicon wafers (or other suitable substrates). Wafers may undergo numerous processing operations, such as physical vapor deposition, chemical vapor deposition, etching, photo-masking, polishing, and/or various other operations. In a continuous effort to reduce the cost of semiconductor devices, multi-layer stacks of dies, insulating films, patterned and/or doped semiconducting films, and/or other features are often deposited on a single wafer, resulting in high aspect ratio devices, which are used, e.g., in 3D flash memory devices and other applications. Deposition, patterning, etching, polishing, etc., of stacks of multi-layered structures often result in significant stresses applied to the underlying wafers. Such stresses lead to both an out-of-plane distortion and an in-plane distortion of features supported by the wafers. These distortions result in misalignment of deposited features and can significantly degrade quality of manufactured devices.

### BRIEF DESCRIPTION OF THE DRAWINGS

The present disclosure will be understood more fully from the detailed description given below and from the accompanying drawings of various embodiments of the disclosure.

FIGS. 1A-1K illustrate schematically a portion of a process of manufacturing of a high aspect ratio structure with unification of back side stress-compensation layer deposition and front side feature protection, according to at least one embodiment.

FIGS. 2A-E illustrate schematically a process of correcting a substrate deformation using a stress-mitigation beam applied to the back side of a substrate, according to at least one embodiment.

FIG. 3 illustrates an example Zernike polynomial decomposition of one actual deformation (top left) of a substrate, in arbitrary units, into a paraboloid bow deformation (top right), a saddle deformation (bottom left), and a residual deformation, (bottom right), according to at least one embodiment.

FIG. 4 is a flowchart illustrating an example method of mitigation of anisotropic substrate stress and deformation using stress-compensation beams, in accordance with at least one embodiment.

FIG. 5 is a flowchart illustrating an example method of determining settings for beam irradiation, according to at least one embodiment.

FIG. 6A-6B illustrates schematically an irradiation system capable of performing irradiation of stress compensation layers, according to at least one embodiment.

FIGS. 7A-7D illustrate schematically handling of deposition of a front side protection layer and a back side stress-compensation layer near edges of substrates, according to at least one embodiment.

FIG. 8 depicts a block diagram of an example computer system capable of supporting operations of the present disclosure, according to at least one embodiment.

The present disclosure will be understood more fully from the detailed description given below and from the accompanying drawings of various embodiments of the disclosure.

### SUMMARY

In one embodiment, disclosed is a method that includes covering a plurality of features on a front side of a substrate with a feature protection layer, forming a stress-compensation layer (SCL) on a back side of the substrate, wherein the SCL causes a reduction of deformation of the substrate, and removing, via a unified processing operation, the feature protection layer and a subplurality of features of the plurality of features.

In another embodiment, disclosed is a method that includes covering a plurality of features on a front side of a substrate with a feature protection layer, and forming a stress-compensation layer (SCL) on a back side of the substrate, wherein the SCL causes a reduction of deformation of the substrate, and wherein the feature protection layer and the SCL are formed using a same processing chamber.

In another embodiment, disclosed is a semiconductor manufacturing system comprising one or more processing chambers to cover a plurality of features on a front side of a substrate with a feature protection layer, form a stress-compensation layer (SCL) on a bottom side of the substrate, wherein the SCL causes a reduction of deformation of the substrate, and remove, via a unified processing operation, the feature protection layer and a subplurality of features of the plurality of features.

### DETAILED DESCRIPTION

Modern technology often aims to maximize chip area utilization by manufacturing three-dimensional devices with vertical stacks of many layers of semiconductor structures. For example, in NAND flash memory devices, lateral relative arrangement (CMOS near Array, or CnA) of memory cells (e.g., floating gate transistors) and peripheral transistors (e.g., CMOS circuitry used to support write/read operations with memory cells) has mostly given way to a vertical arrangement (CMOS under Array, or CuA) in which peripheral CMOS circuitry is disposed under an array of memory cells. In some instances, stacks of layers of memory cells can be manufactured on top of other stacks creating a structure in which precise alignment of various features within the layers is important for proper functioning of the manufactured devices. In one example, a stack of multiple (e.g., tens, hundreds, or more) alternating oxide (O) and nitride (N) layers (e.g., silicon oxide and silicon nitride layers, in one example) can be deposited on top of a substrate, e.g., silicon wafer. Although O and N layers are often referenced throughout the instant disclosure, various other additional layers/films can be deposited on wafers, e.g., polycrystalline silicon layers, carbon and polymer protective films, and/or the like. In another example of a three-dimensional (3D) Dynamic Random-Access Memory (DRAM) manufacturing, a stack of alternating Si₁₋ₓGeₓ (SiGe) alloy layers and silicon (e.g., epitaxial silicon) layers can be deposited on top of a silicon substrate to form.

A mask (e.g., carbon mask) can be deposited on top of the ON or Si/SiGe stack and covered with a photoresist layer with a defined pattern of holes (channel holes), slits, and/or various other openings that are to be transferred to the stack of ON or Si/SiGe layers via the mask. A photolithography step can then be performed to open the mask according to the defined pattern (with the photoresist material protecting unexposed areas of the mask from light) and allow access to the stack of ON or Si/SiGe layers. An etching process can be carried out to etch the regions of the ON or Si/SiGe layers located under the opened portions of the mask to form deep vertical channels and/or slits that can extend down the depth of the stack. The slits can then be used to deliver target materials across various ON or Si/SiGe layers, e.g., to replace N or SiGe layers with layers of conducting materials (such as Tungsten, Molybdenum, etc.) and form multi-layered transistor arrays within the vertical channels, and/or the like.

The arrays of transistors and/or other features deposited into the stack of layers have to be precisely aligned with the matching structures deposited on the top surface of the wafer, e.g., source lines of conducting circuits that support electronic operations of the transistor arrays. Furthermore, one or more additional stacks of layers can be deposited on top of the previously deposited stacks, e.g., to increase the vertical count of memory cells/transistors and, respectively, increase density of cells per area of the NAND or 3D DRAM device. Processing such additional stacks can be performed as described above, e.g., by placing another mask above an additional stack, opening the mask, and etching vertical channels/slits through the additional stack(s). The channels etched through the top stack(s) have to align with the corresponding channels etched in the bottom stack(s), to ensure that good electrical contacts are formed between corresponding arrays of memory cells.

Alignment of channels, slits, and/or various other features across a vertical stack of multiple layers/films, however, can be hindered by deformation of the wafer, e.g., in-plane and/or out-of-plane deformation. Such deformations can be caused by stresses arising at contacts between the wafer and the stacks of layers, between layers of individual stacks, stresses arising from patterning of features within the layers, and/or the like. Stresses and deformations can result in inoperable and/or sub-optimal devices leading to a corresponding decrease in the yield of the manufacturing process.

Deformation of wafers can be addressed by a number of techniques. For example, a deformed (warped) wafer with various films and features deposited on one side (also referred to as the front side, top side, or main side) can be coated on the back side (also referred to as the bottom side) with a film that exerts compressive stress or tensile stress on the wafer. Such a back side-deposited deformation-correcting film, also referred to as a stress-compensation layer (SCL) herein, can impart a uniform (or global) stress to the entire wafer and reduce deformation of the wafer. Additional stress-mitigation can be achieved by implanting ions into the stress-compensation layer, e.g., using a beam of ions to bombard the SCL to adjust the stress in the SCL and, consequently, to further correct deformation of the underlying wafer. Ion implantation can be performed globally or locally, e.g., to certain selected areas of the wafer, such as wafer edges.

Depositing (or otherwise forming) an SCL on the wafer's back side can involve exposing the back side to the environment of a processing chamber (e.g., deposition chamber) to place an SCL material, on the back side, e.g., silicon nitride, in one example. This is typically performed by handling the wafer using an end effector (e.g., robot blade, electrostatic chuck, etc.) engaging the wafer's front side (with various stacks of features deposited thereon). Alternatively, back side deposition can involve lifting the wafer (e.g., using lift pins or holding the wafer up by the edge) and depositing the SCL from the bottom of a chamber (e.g., a chemical vapor deposition chamber, CVD). In some instances, the lack of intimate (close) coupling between the wafer and the electrode in the plasma-enhanced CVD (PECVD) chamber can limit the attainable stress in the SCL, which, in turn, can control the entitlement for anisotropic stress management (the maximum correctable saddle deformation of the wafer). The use of an electrostatic chuck provides such intimate contact and can increase the attainable stress in the SCL that can be used for saddle-shape deformation correction. To prevent damage to the front side by the end effector, the front side features are usually covered with a protective layer, e.g., a carbon protective layer. After the SCL is formed (and undergoes ion deposition) to reduce wafer deformation, the carbon protective layer is removed (e.g., using ash dry removal or some other stripping technique) to allow access to ON or Si/SiGe layers. The nitride or silicon-germanium layers can then be removed—exhumed—and replaced with a suitable conducting material (such as Mo, W, etc.). Various additional processing operations can be performed.

The described operations are conventionally performed using many different processing chambers. For example, carbon protection layer deposition can be performed in a first deposition chamber, SCL deposition can be performed in a second deposition chamber, stripping of the carbon protective layer can be performed in a third chamber (e.g., a dry ashing chamber), and nitride exhumation can be performed in a wet removal chamber. The number of different processing chambers and operations involved in the manufacturing process increases the cost of device manufacturing, decreases its throughput, and increases exposure of the products to contaminants.

Aspects and embodiments of the present disclosure address these and other challenges of the modern semiconductor manufacturing technology by providing for systems and techniques that streamline processing of multi-stack manufacturing products by unifying some of the back side and front side processing operations. More specifically, as disclosed in more detail below, protection of the wafer's front side can be achieved using a nitride protective layer instead of the carbon layer. This enables deposition of the protective layer and the SCL (e.g., made with the same nitride compound) using a single processing (e.g., deposition) chamber. Likewise, removal of the protective layer can be performed together with nitride exhumation via a single—unified—operation using the same process step (e.g., wet removal bath). This reduces the number of deployed processing chambers and the complexity of the processing operations.

Advantages of the disclosed embodiments include but are not limited to a significant reduction of the costs of manufacturing of semiconductor products, including but not limited to vertically stacked structures or other high aspect ratio features in vertically grown semiconductor devices.

A “wafer,” as used herein, refers to any substrate or material surface formed on a substrate upon which film processing is performed during a fabrication process. For example, a wafer surface on which processing can be performed includes materials such as silicon, silicon oxide, silicon nitride, strained silicon, silicon on insulator, carbon doped silicon oxides, amorphous silicon, doped silicon, germanium, gallium arsenide, glass, sapphire, plastic, and any other materials such as metals, metal nitrides, metal alloys, and other conductive materials, depending on the application. Wafers include, without limitation, semiconductor wafers. Wafers may be exposed to a pretreatment process to polish, etch, reduce, oxidize, hydroxylate, anneal, UV cure, e-beam cure and/or bake the substrate surface. In addition to film processing directly on the surface of the wafer itself, any of the film processing steps disclosed may also be performed on an underlayer formed on the wafer as disclosed in more detail below, and the term “wafer surface” is intended to include such underlayer as the context indicates. Thus, for example, where a film/layer or partial film/layer has been deposited onto a wafer surface, the exposed surface of the newly deposited film/layer becomes the wafer surface. In some embodiments, wafers have a thickness in the range of 0.25 mm to 1.5 mm, or in the range of 0.5 mm to 1.25 mm, in the range of 0.75 mm to 1.0 mm, or more. In some embodiments, wafers have a diameter of about 10 cm, 20 cm, 30 cm, or more.

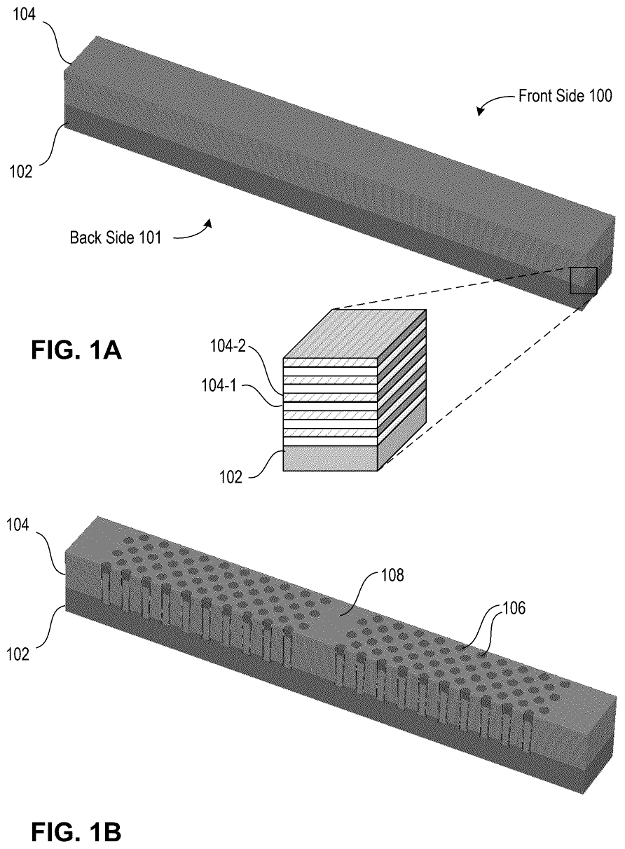

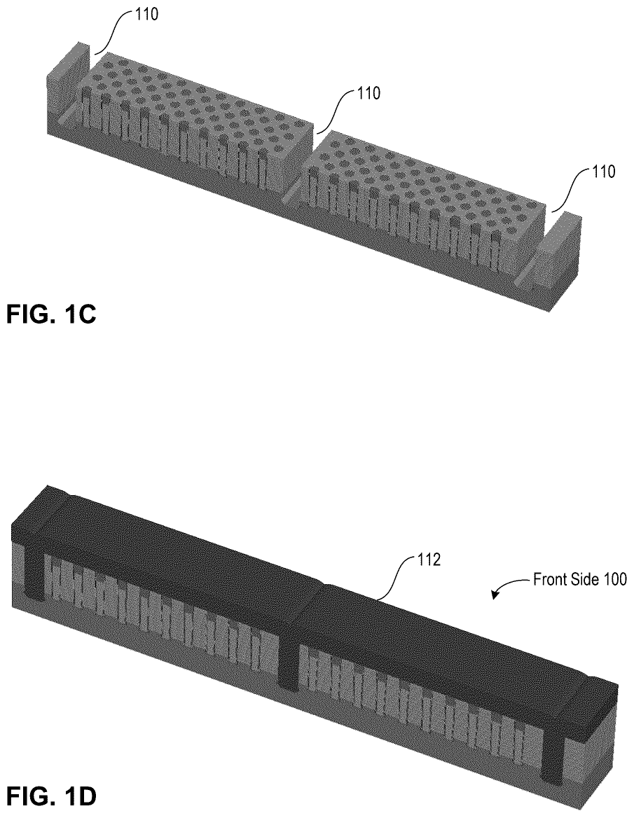

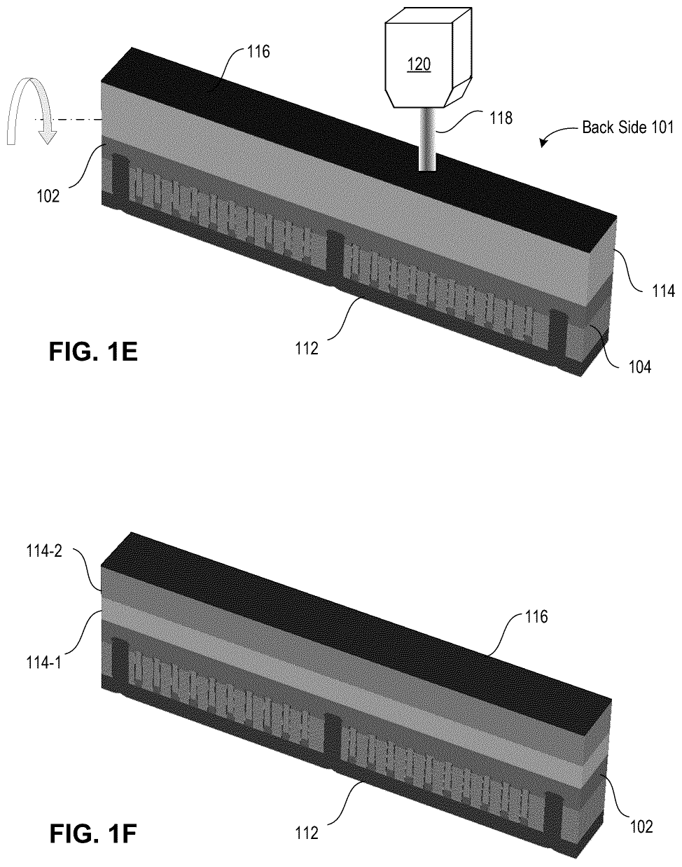

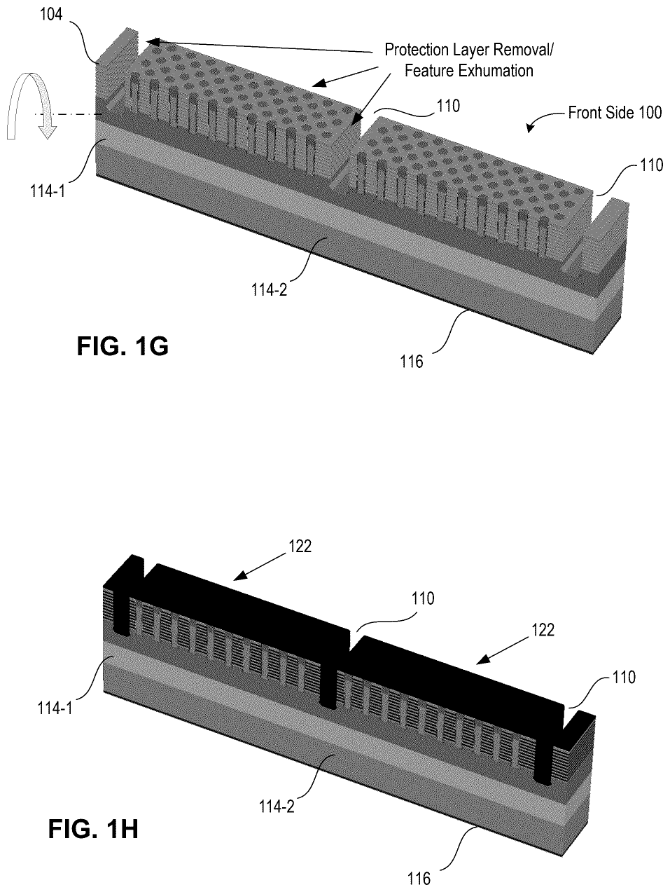

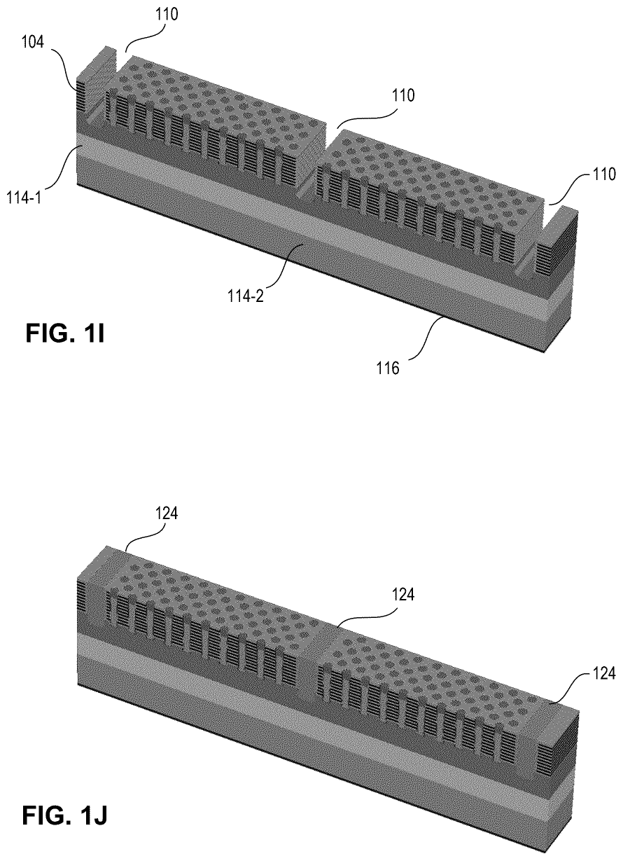

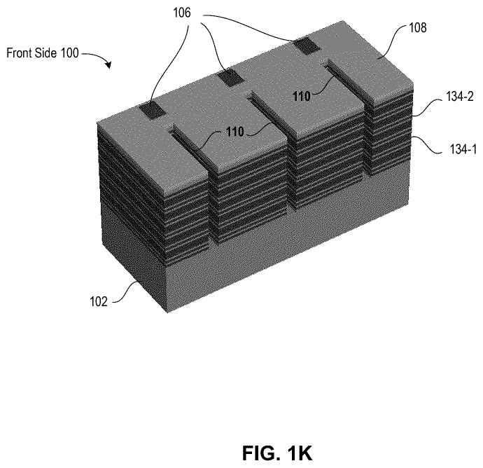

FIGS. 1A-1K illustrate schematically a portion of a process of manufacturing of a high aspect ratio structure with unification of back side stress-compensation layer deposition and front side feature protection, according to at least one embodiment. It should be understood that FIGS. 1A-1K illustrate merely some possible applications of the disclosed techniques and that manufacturing of numerous other structures, features, and devices can be performed using the same or similar techniques. FIGS. 1A-1J illustrate processing of 3NAND devices and FIG. 1K illustrates a 3D DRAM device. FIG. 1A illustrates a high-aspect structure (referred to as “sample” herein) having a front side 100 (device side) and a back side 101 (wafer side). A substrate 102 (e.g., a silicon wafer) of any suitable size, e.g., 30 cm, supports a stack 104 of layers/films grown (or deposited) on substrate 102. Stack 104 can be a stack of alternating O and N layers, which can include any number (e.g., tens or hundreds or more) of periodically repeated O and N layers (or some other stack of features). A callout portion of FIG. 1A illustrates the top portion of substrate 102 with five first O layers 104-1 and the equal number of N layers 104-2. In some embodiments, the thickness of each O layer 104-1 or N layer 104-2 can range from 10 nm (or less) to 100 nm (or more), e.g., can be 20-30 nm, in some embodiments. The height of stack 104 can be of the order of 10 μm. In some embodiments, the height of stack 104 can be between 1-30 μm. In some embodiments, O layers 104-1 and N layers 104-2 can be manufactured using a CVD technique or some other suitable techniques.

As illustrated in FIG. 1B, channels 106 can be formed on the front side 100 of the sample extending through the depth of stack 104. For example, a mask (not shown in FIG. 1B) can be deposited on top of stack 104 and a photoresist layer (now shown in FIG. 1B) can be deposited on top of the mask. A photolithography can then be used to create a target pattern in the photoresist layer, e.g., a pattern of channel holes to be transferred to the mask and then further to stack 104. More specifically, an etch process, e.g., Mask Open Etch, can be used to transfer the target pattern to the mask. The Mask Open etch creates a pattern of channels 106 (as well as any other features, including but not limited to slits, and/or any other openings) in the mask. An additional etch process—a channel hole etch, memory hole etch, dielectric etch—is then used to transfer the pattern of channels (and/or other features) to stack 104 forming channels 106 that can extend towards substrate 102, in some embodiments. (The etch process can consume the mask; unconsumed parts of the mask can be removed, e.g., dissolved or evaporated.) Although, for simplicity, FIG. 1B illustrates formation of cylindrical channels 106, other structures, e.g., slits or any other vertical features can be also etched in a similar manner. The channels 106 can be (fully or partially) filled with an Oxide Nitride Oxide Silicon Oxide (ONOSO) stack. For example, the surface of the channels 106 can be coated with a conduction material and the cores of the channels can be filled with an ONOSO stack. In some embodiments, an insulating layer 108 (e.g., an oxide layer) can be deposited on top of stack 104 to facilitate electric separation of different channels 106.

As illustrated in FIG. 1C, slits 110 can then be etched across the depth of stack 104 to form electrically separated blocks, e.g., NAND memory blocks. As illustrated in FIG. 1D, a protection layer 112 can then be deposited on the front side 100 of the sample. In some embodiments, protection layer 112 can be made of silicon nitride (Si₃N₄). In other embodiments, material different from silicon nitride can be used. During deposition of protection layer 112, slits 110 can also be filled with the same material (e.g., silicon nitride). In some embodiments, the thickness of protection layer 112 can be between 500-2000 nm but can be less than 500 nm or more than 2000 nm, in other embodiments. In some embodiments, the stress on the front side protection layer can be minimized. In other embodiments, the stress can be tuned to be either tensile or compressive to a specific value to achieve a target wafer bow.

As illustrated in FIG. 1E, the sample can be flipped, e.g., by removing the sample from a processing chamber, rotating the sample, and reinserting the sample back into the processing chamber. These steps can be performed on the same tool by flipping the wafer in the Factory Interface (FI) of the mainframe of the process tool. A stress-compensation layer (SCL) 114 can be deposited (e.g., using CVD or other techniques) on the back side of substrate 102. In other embodiments, SCL 114 can be made from a material that is different from a material of protection layer 112. In some embodiments, SCL 114 can be made of the same material, e.g., silicon nitride Si₃N₄, as protection layer 112. In some embodiments, protection layer 112 can be a low-stress layer while SCL 114 can have a higher stress. The level of stress in SCL 114 can be set at SCL 114 deposition by controlling conditions in the processing chamber during deposition of SCL 114, including but not limited to concentration of argon and/or nitrogen atoms in the environment of the processing chamber, voltage, temperature, and/or the like. In some instances, SCL 114 can have a tensile stress while, in other instances, SCL 114 can have a compression stress. The type of SCL (tensile vs. compressive) can be determined by a (measured and/or inferred) sign of stress in substrate 102 prior to the SCL deposition. Similarly, the magnitude of stress of SCL can be determined (measured and/or inferred) based on a magnitude of stress in substrate 102.

As further illustrated in FIG. 1E, another protection layer 116 (cap layer or SCL protection layer) can be deposited (or otherwise formed) on SCL 114. Cap layer 116 protects SCL 114 during subsequent operations of the process (as described below). In some embodiments, cap layer 116 can be an oxide layer, e.g., a silicon oxide (SiO₂) layer. The thickness of cap layer 116 can be between 5-30 nm but can be less than 5 nm or more than 30 nm, in some embodiments.

As further illustrated in FIG. 1E, a stress-mitigation beam 118 can be applied to SCL 114 to deliver a position-dependent dose of particles and/or photons n(x, y), where x, y are in-plane coordinates within the wafer/SCL plane. Stress-mitigation beam 118 can be generated by a suitable collimating and focusing column 120. Application of stress-mitigation beam 118 causes stress in the sample that contains substrate 102, stack 104, and SCL 114 to decrease, resulting in the flattening of the sample (reduced deformation).

As illustrated in FIG. 1F, application of stress-mitigation beam 118 causes SCL 114 to have a first portion 114-1 and a second portion 114-2 with different elastic characteristics. Stress in the first portion 114-1 can be similar to the stress that existed in SCL 114 prior to application of the stress-mitigation beam 118. Stress in the second portion 114-2 can be reduced (to a predetermined amount) compared to the stress in the first portion 114-1 (as a result of the interaction of the particles of the beam with the atomic structure of SCL 114).

As illustrated in FIG. 1G (again showing the flipped sample, with the front side 100 facing up), in a 3DNAND device, removal of the protection layer can be performed together (in a single processing operation) with exhumation of nitride (N) layers from the gate stack 104. For example, the sample can be exposed to an acidic environment, e.g., by submerging it in hot phosphoric acid. The acidic environment removes the protection layer (protection layer 112 in FIG. 1D-1F) and gains access to N layers of stack 104 via slits 110. The nitride layers are then also removed by the acidic environment while keeping oxygen (O) layers intact. Cap layer 116 protects SCL 114 from the action of the acidic environment.

As illustrated in FIG. 1H, the opened (by the acidic environment) slits 110 and gaps left by the removed N layers, can be filled with a conducting material, e.g., Mo, W, and/or some other suitable conducting material 122. In particular, conducting material 122 fills slits 110 and, from slits 110, moves into gaps between the O layers. The excess of the conducting material filling slits 110 and covering the top of stack 104 can now be removed, resulting in the structure shown in FIG. 1I. The conducting material removal can be performed using wet or dry etching. The conducting material remaining in the sample shown in FIG. 1I is confined to the gaps between the O layers. As illustrated in FIG. 1J, slits 110 can then be filled with insulating material to form insulating spacers 124.

FIG. 1K illustrates schematically manufacturing of a 3D DRAM device using a combination of back side stress-compensation layer deposition and front side feature protection. A substrate 102 (e.g., a silicon wafer) supports a stack 104 of epitaxially grown silicon layers 134-1 interspersed with SiGe layers 134-2. The stack can be covered with an insulating (e.g., oxygen) layer 108. As illustrated in FIG. 1K, channels 106 (e.g., bitline channels) can be formed on the front side of the sample extending through the depth of the stack of layers, e.g., substantially as described in conjunction with FIGS. 1A-1D, e.g., using a mask, a photoresist layer, and the photolithography techniques. Similarly, slits 110 can then be etched through the depth of the stack to form DRAM memory blocks. A protection layer (e.g., a silicon nitride layer) can then be deposited on the front side 100 of the sample, e.g., substantially as described in conjunction with FIG. 1D. The sample can then be flipped, e.g., as illustrated in FIG. 1E, and an SCL can be deposited (not shown in FIG. 1K) and mitigated using a suitably chosen stress-mitigation beam. The combination of the SCL and the stress-mitigation beam cause the sample to flatten. The protection layer can then be removed from the sample followed with exhumation of SiGe (e.g., using a suitable acidic environment). The exhumed SiGe layers can be then be filled with a conducting material, e.g., Mo, W, and/or the like, and slits 110 can then be filled with an insulating material.

In some embodiments, prior to irradiating SCL 114 with stress-mitigation beam 118, the amount of stress in substrate 102 (with films and mask deposited thereon) can be determined by measuring a profile h(\vec{r}) of substrate 102. The profile h(\vec{r}) can refer to the vertical coordinate of the bottom surface of substrate 102. In some instances, stress in substrate 102 can be uniform and isotropic, σₓₓ≈σ_{yy}. In some instances, stress in substrate 102 can be anisotropic, σₓₓ≠σ_{yy}. Certain feature patterns can result in stresses that are compressive along one direction, e.g., σₓₓ>0, and tensile along a perpendicular direction, σ_{yy}<0, resulting in saddle-shaped wafers. Such saddle-shaped features can arise, for example, in stacks of materials with directional patterning, e.g., patterning of wordlines, bitlines, and/or other suitable features in NAND devices, DRAM devices, and/or the like.

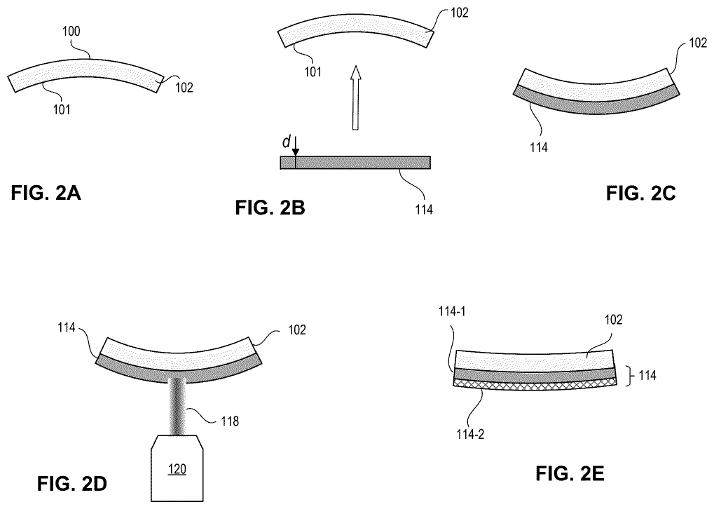

In some embodiments, a vertical profile of substrate 102 deformation z=h(\vec{r}) can be measured using optical metrology (e.g., optical interferometry) techniques. In some embodiments, wafer deformation z=h(\vec{r}) can be measured after a stack 104 of layers/films is deposited on substrate 102. The wafer profile h(\vec{r}) can then be represented via a number of parameters that qualitatively and quantitatively characterize geometry of the wafer deformation, e.g., a set of Zernike (or a similar set of) polynomials, h(\vec{r})=ΣⱼAⱼZⱼ(\vec{r}). Consecutive coefficients A₁, A₂, A₃, A₄ . . . represent weights of specific geometric features (elemental deformations) of substrate 102 described by the corresponding Zernike polynomials Zⱼ(\vec{r}). In some embodiments, a material of SCL 114 mask can be selected based on the sign of a paraboloid bow coefficient A₄. In some embodiments, selection of a thickness d of SCL 114 can be made based on a value of the paraboloid bow coefficient A₄. As illustrated in FIGS. 2A-2E, thickness d of SCL 114 can be selected to overcorrect the wafer deformation to some degree. The overcorrection can be chosen in conjunction with a type of stress-mitigation beam 118 (e.g., ion implants, photons, electrons, etc.), a type of implant species, energy, and dose to ensure maximum effect from the stress mitigation. Stress in the combined structure of the wafer, films, and SCL 114 can then be modified by stress-mitigation beam 118 that strikes SCL 114 and changes its crystal (or amorphous) structure. Substitution defects and/or vacancies created by beam 118 mitigate (e.g., reduce) stress in SCL 114 and can reduce the degree of stress overcorrection caused by SCL 114 deposition. This causes the wafer to flatten.

FIGS. 2A-E illustrate schematically a process of correcting a substrate deformation using a stress-mitigation beam applied to the back side of a substrate, according to at least one embodiment. FIG. 2A depicts substrate 102 having a deformation, which can include a paraboloid bow deformation (with positive coefficient A₄>0, as illustrated) and can further include other deformations, including saddle deformation, residual deformation, etc. The wafer's front side 100 can include any number of features, e.g., deposition and/or etching patterns, a stack of layers/films, and/or any other structures. FIG. 2B illustrates deposition of SCL 114 on the back side 101 of substrate 102. SCL 114 can be (or include) a silicon nitride layer or some other type of material. In some embodiments, SCL 114 can include layers of multiple materials. In some embodiments, a material of SCL 114 can be selected in view of the sign of coefficient A₄. For example, for a positive bow, A₄>0, SCL 114 can be selected to have a compressive stress (as illustrated in FIGS. 2B-2E). Conversely, for a negative bow, A₄<0, SCL 114 can be selected to have a tensile stress. SCL 114 can be deposited using any suitable deposition techniques including physical vapor deposition (e.g., sputtering), chemical vapor deposition (e.g., plasma-assisted deposition), epitaxy, exfoliation, and/or the like. SCL 114 can be deposited using any suitable deposition techniques including physical vapor deposition (e.g., sputtering), chemical vapor deposition (e.g., plasma-assisted deposition), epitaxy, exfoliation, and/or the like. Deposition can be performed at room temperature or at temperatures different from room temperature (e.g., at an elevated temperature). In some embodiments, thickness d of SCL 114 can be selected to overcorrect the wafer deformation to some degree, e.g., as illustrated in FIG. 2C where a positive paraboloid is overcorrected to a negative paraboloid bow. The thickness-dependent paraboloid bow correction A_{corr}(d) changes wafer deformation from h(r, ϕ) to h_{corr}(r, ϕ):

$${h}_{corr} ( r , ϕ ) = h ( r , ϕ ) + {A}_{corr} ( d ) \cdot {Z}_{4} ( r , ϕ ) .$$

The degree of overcorrection can be chosen in conjunction with a type and parameters (e.g., energy, dose, etc.) of a specific stress-mitigation beam 118 to be used on SCL 114. The overcorrection can make the combined structure of substrate 102 and SCL 114 susceptible to further control of stress (and thus control of deformation of the wafer h_{corr}(r, ϕ)). As illustrated in FIG. 2D, collimating and focusing column 120 can generate a stress-mitigation beam 118 that strikes SCL 114 and changes its elastic properties, e.g., by creating vacancies, breaking crystal bonds, depositing ions, and/or via any other applicable mechanisms. Stress-mitigation beam 118 can carry photons, electrons, silicon ions, phosphorus ions, argon ions, neon ions, xenon ions, krypton ions, and/or the like. In some embodiments, the energy and type of ions in stress-mitigation beam 118 can be selected to limit the implanted ions to the volume of SCL 114 without allowing the ions to reach substrate 102 (and/or any layers/films deposited on substrate 102). Ions that lodge in SCL 114 create substitution defects therein. Additionally, the ions leave a trail of vacancy defects along paths of propagation in SCL 114. The substitution defects and/or vacancies mitigate (e.g., reduce) stress in SCL 114 and can reduce the degree of stress overcorrection caused by the SCL deposition. This causes the combination of substrate 102 and SCL 114 to flatten.

In some embodiments, the number of ions ΔNᵢ deposited per small area ΔA=ΔₓΔ_{y} (or the total amount of photon energy applied to this area) of substrate 102 can be determined using simulations (performed as described in more detail below) based on the local value of the corrected deformation h_{corr}(r, ϕ), which may include a saddle deformation, a residual deformation, and the part of the paraboloid bow deformation A_{corr}(d)+A₄ that has been overcorrected by the deposition of stress-compensation layer 118. The target local density n(x, y)=ΔNᵢ/ΔₓΔ_{y} of the ions can be delivered by controlling the scanning velocity v of stress-mitigation beam 118. In some embodiments, stress-mitigation beam 118 has a profile that can be approximated with a Gaussian function, e.g., the ion flux j(ρ)=j₀ exp(−x²/a²−y²/b²), where x and y are Cartesian coordinates, j₀ is the maximum ion flux at the center of the beam, and a and b is are characteristic spreads of the beam along the x-axis and y-axis, respectively. Correspondingly, a point that is located at distance y from the path of the center of the beam receives an ion dose that includes the following number of ions:

$$\frac{Δ {N}_{i}}{Δ x Δ y} = \frac{{j}_{0}}{v} {{\int }^{∞}}_{- ∞} {dxe}^{- {x}^{2} / {a}^{2} - {y}^{2} / {b}^{2}} = \frac{{j}_{0} \sqrt{π}}{va} {e}^{- {y}^{2} / {b}^{2}} .$$

Correspondingly, by reducing the scanning velocity v, the number of ions received by various regions of SCL 114 can be increased, and vice versa. Additionally, stress-mitigation beam 118 can perform multiple scans with different offsets y so that various points of SCL 114 receive multiple doses of ions with different factors e^{-y}^{²}^{/b}^{²} that can average to a target dose. For example, after n passes of stress-mitigation beam 118, each made with a respective velocity vₖ at a different distance yₖ from the center of the beam to the area ΔₓΔ_{y}, the total dose of ions (or amount of electromagnetic radiation) received by this area will be

$$n ( x , y ) = \frac{Δ {N}_{i}}{Δ x Δ y} {\vert}_{total} = {j}_{0} \sqrt{π} {\sum }_{k = 1}^{n} \frac{{e}^{- {y}_{k}^{2} / {b}^{2}}}{{av}_{k}} .$$

As illustrated in FIG. 2E, a stress-mitigated portion 114-2 of SCL 114 and results in a significant mitigation of deformation of substrate 102, including saddle and residual deformations.

In some embodiments, the intensity and/or total amount of irradiation per various areas of substrate 102 can be determined using simulations, e.g., Monte Carlo simulations. The Monte Carlo simulations can be performed for a film made of the actual material used in SCL deposition and having a specific thickness d. An initial Monte Carlo simulation can be performed for specific baseline (default) conditions of the particle irradiation (e.g., default settings of an ion implantation apparatus). The baseline conditions can include a default type of particles, a default energy of the particles, a default dose of particles to be applied to SCL 114 (e.g., a default velocity of scanning and a default scanning pattern), and the like. The baseline conditions can subsequently be modified (e.g., optimized) using the Monte Carlo simulations. The Monte Carlo simulations can use calibration data collected (measured) for actual particle irradiation performed for various ion/photon/electron energies, types of ions, types and materials of masks/layers, angles of particle incidence on the films, and/or the like.

In some embodiments, the implantation map n(\vec{r}) can be computed using an influence function G(\vec{r}; \vec{r}′) that characterizes a response (e.g., deformation) at a point \vec{r} of the wafer as caused by a point-like force applied at another point \vec{r}′ of substrate 102. In some embodiments, the influence function G(\vec{r}; \vec{r}′), also known as the Green's function, can be determined from computational simulations or from analytical calculations. In some embodiments, the influence function can be determined from one or more experiments, which can include performing ion implantation into a film deposited on a reference wafer.

In some embodiments, wafer deformation h(\vec{r})=h_{quad}(\vec{r})+hᵣₑₛ(\vec{r}) can be represented (decomposed) as a combination of a quadratic h_{quad}(\vec{r}) and residual (non-quadratic) hᵣₑₛ(\vec{r}) contributions. The quadratic deformation can include a parabolic (paraboloid) part hₚₐᵣ(\vec{r}), which has the complete axial symmetry, and a saddle part h_{saddle}(\vec{r}). The thickness d of SCL 114 can be computed (or empirically determined) in such a way that the mask is to apply a desired target stress to substrate 102. To eliminate a non-uniform saddle deformation, SCL 114 can be of such thickness/material that turns the saddle deformation into a cylindrical deformation having a definite sign throughout the area of substrate 102. The uniform-sign cylindrical deformation (as well as a residual higher-order non-quadratic deformation) can then be mitigated with irradiation by stress-mitigation beam 118. In some embodiments, a cylindrical decomposition is not unique and can be either positive (upward-facing cylindrical deformation) or negative (downward-facing cylindrical deformation). Both decompositions can be analyzed and a decomposition that enables a more effective stress mitigation can be selected. For example, a decomposition that is characterized by a smaller parabolic bow deformation can be selected. The parabolic bow deformation can be mitigated using a choice of SCL 114 (e.g., type and thickness) while the remaining cylindrical deformation (and the higher-order residual deformation) can be addressed by appropriately selected ion or photon irradiation doses n(\vec{r}).

In some embodiments, mitigation of a cylindrical deformation or a saddle deformation can include identifying principal axes (directions) of the cylinder/saddle and a magnitude of the cylindric/saddle deformation and directing stress-mitigation beam 118 into appropriately selected edge regions of SCL 114. For example, individual edge regions to which the beam 118 is directed can have a width that is at or below 30% of a diameter of substrate 102. Residual higher-order (ripple) deformations can then be mitigated with further irradiation into the area of SCL 114.

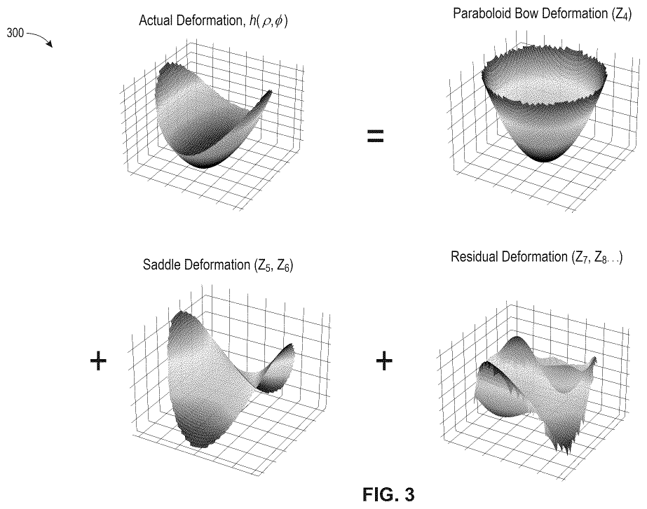

Some of these techniques will now be described in more detail. In one embodiment, a vertical profile of wafer deformation z=h(\vec{r}) can be measured using optical metrology techniques. For example, an interferogram of the profile h(\vec{r}) can be obtained using optical interferometry measurements. The wafer profile h(\vec{r}) can then be represented via a number of parameters that qualitatively and quantitatively characterize geometry of the wafer deformation. In some embodiments, a set of Zernike (or a similar set of) polynomials may be used to represent the wafer profile,

$$h ( \vec{r} ) = {\sum }_{j} {A}_{j} {Z}_{j} ( \vec{r} ) ,$$

where the planar radius-vector \vec{r}=(r, ϕ) may be represented as the radial coordinate r and the polar angle ϕ within the (average) plane of the wafer. Consecutive coefficients A₁, A₂, A₃, A₄ . . . represent weights of specific geometric features (elemental deformations) of substrate 102 described by the corresponding Zernike polynomials Z₁(r, ϕ), Z₂(r, ϕ), Z₃(r, ϕ), Z₄(r, ϕ) . . . . (Herein, the Noll indexing scheme for the Zernike polynomials is being referenced.) The first three coefficients are of less interest as they describe a uniform shift of substrate 102 (coefficient A₁, associated with the Z₁(r, ϕ)=1 polynomial), a deformation-free x-tilt that amounts to a rotation around the y-axis (coefficient A₂, associated with the Z₂(r, ϕ)=2r cos 0 polynomial), and a deformation-free x-tilt that amounts to a rotation around the x-axis (coefficient A₃, associated with the Z₃(r, ϕ)=2r sin ϕ polynomial) that can be eliminated by a realignment of the coordinate axes. The fourth coefficient A₄ is associated with Z₄(r, ϕ)=\sqrt{3}(2r²−1) and characterizes an isotropic paraboloid deformation (“bow”). The fifth A₅ and the sixth A₆ coefficients are associated with Z₅(r, ϕ)=\sqrt{6}r² sin 2ϕ and Z₆(r, ϕ)=\sqrt{6}r² cos 2ϕ polynomials, respectively, and characterize a saddle-type deformation. The A₅ coefficient characterizes a saddle shape that curves up (A₅>0) or down (A₅<0) along the diagonal y=x and curves down (A₅>0) or up (A₅<0) along the diagonal y=−x. The A₆ coefficient characterizes a saddle shape that curves up (A₆>0) or down (A₆<0) along the x-axis and curves down (A₆>0) or up (A₆<0) along the y-axis. The higher coefficients A₇, A₈, etc., characterize progressively faster variations of the wafer deformation h(r, ϕ) along the radial direction, along the azimuthal direction, or both and collectively represent a residual deformation, hᵣₑₛ(r, ϕ)=h(r, ϕ)−Σⱼ₌₄⁶AⱼZⱼ(r, ϕ). FIG. 3 illustrates an example Zernike polynomial decomposition 300 of one actual deformation h(r, ϕ) (top left) of a substrate (e.g., substrate 102), in arbitrary units, into a paraboloid bow deformation A₄Z₄(r, ϕ) (top right), a saddle deformation A₅Z₅(r, ϕ)+A₆Z₆(r, ϕ) (bottom left), and a residual deformation, hᵣₑₛ(r, ϕ) (bottom right), according to at least one embodiment.

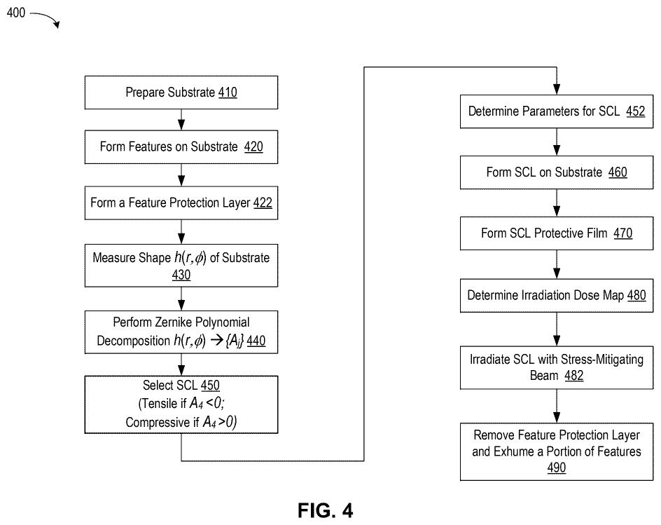

FIG. 4 is a flowchart illustrating an example method 400 of mitigation of anisotropic substrate stress and deformation using stress-compensation beams, in accordance with at least one embodiment. Method 400 can be performed using a semiconductor manufacturing system that includes one or more processing chambers, e.g., deposition chamber(s), plasma chamber(s), etching chamber(s), polishing chamber(s), film removal chamber(s), beam irradiation chamber(s), optical inspection chamber(s), and/or the like. The processing chambers can be connected to one or more transfer chambers, which can be equipped with robot(s) to handle substrates, e.g., moving substrates into and out of processing chambers. The transfer chamber can further be connected to a load-lock chamber (Front-End Interface) that can be coupled to one or more Front Opening Unified Pod carriers that hold bare substrates, processed substrates, partially processed substrates, and/or the like. Operations performed by the semiconductor manufacturing system, including any, some or all operations of method 400, can be performed responsive to instructions issued by a suitable computing device having a processing logic and memory to store the instructions.

At block 410, method 400 can include preparing a substrate, including but not limited to obtaining a bare substrate, preprocessing the bare substrate, e.g., polishing the substrate, removing stains and/or residue from the substrate, and/or the like, and/or performing any number of similar operations. At block 420, method 400 can continue with forming one or more features on the front side of a substrate. The features can include any number of patterns, layers, films, slits, masks, holes, and/or the like (e.g., as illustrated in FIGS. 1A-1C). For example, the features can include a layer of a conducting material, which can include source lines (or any additional interconnect) to be used as part of memory cell (transistor) circuitry. In some embodiments, the features can include a first set of layers that include oxygen and a second set of layers that include nitrogen, the second set of layers interspaced with the first set of layers. In some embodiments, the first set of layers can include silicon and the second set of layers can include a silicon-germanium alloy. Such layers can be used as hosts of memory cells and separations between memory cells. At block 422, method 400 can include depositing, or otherwise forming, a feature protection layer (e.g., as illustrated in FIG. 1D) that covers features formed, e.g., on a front side of the substrate. The feature protection layer protects the formed features during end effector handling of the substrate. In some implementations, the plurality of features includes a first set of layers comprising oxygen, and a second set of layers comprising nitrogen. In some implementations, the plurality of features includes a first set of layers comprising silicon, and a second set of layers comprising a silicon-germanium alloy. The second set of layers can be interspaced with the first set of layers

At block 430, method 400 includes obtaining optical inspection data, including measurement of a shape of the substrate. Inspection data can characterize a profile of the deformation of the substrate, e.g., displacement of a surface (e.g., the bottom surface) of the substrate as a function of some suitable in-plane coordinates, e.g., polar coordinates z=h(r, ϕ), Cartesian coordinates, z=h(x, y), or some other coordinates. At block 440, method 400 includes decomposition of the determined shape over a suitable set of polynomials, e.g., Zernike polynomials, and obtaining a set of polynomial expansion coefficients, {Aⱼ}=(A₁, A₂, A₃), A₄, A₅, A₆, A₇, . . . , each coefficient in the set characterizing a degree of presence of a particular elemental geometric shape in the substrate's deformation.

In some embodiments, method 400 can include a decision-making block 450 to select a type of SCL to be used with the substrate. For example, a decision at block 450 can be made based on the coefficient that determines a degree of parabolicity of the deformation, e.g., coefficient A₄. If the substrate is curved downwards (towards the back side of the substrate), A₄<0, a compressive SCL can be selected for the back side deposition at block 450. If A₄>0, a tensile SCL can be selected for back side deposition. At block 452, parameters for the SCL can be determined. Operations of block 452 can include determining a type of a material for the SCL to be deposited and a thickness d of the SCL. In some embodiments, this determination can be made based on multiple expansion coefficients (more than just the paraboloid bow coefficient A₄) from the set {Aⱼ} or the full profile h(r, ϕ). In one specific non-limiting example, the thickness d can be determined as follows. First, a target paraboloid deformation Ã₄ can be determined that is sufficient to overcompensate for the measured substrate deformation, e.g., for h(r, ϕ)<0, the following condition can be satisfied:

$${\tilde{A}}_{4} {Z}_{4} ( ρ , ϕ ) + h ( r , ϕ ) ≡ ( {\tilde{A}}_{4} + {A}_{4} ) {Z}_{4} ( ρ , ϕ ) + {A}_{5} {Z}_{5} ( ρ , ϕ ) + {A}_{5} {Z}_{6} ( ρ , ϕ ) + … > 0.$$

In other words, the target paraboloid deformation Ã₄ can be chosen sufficiently large to compensate for the paraboloid deformation (A₄), saddle deformation (A₅ and A₆) and the residual deformation (A₇ and higher coefficients). In some embodiments, the target paraboloid deformation Ã₄ can be selected with at least an excess magnitude A_{E} over the minimum needed to overcompensate for the substrate deformation, e.g.,

$${\tilde{A}}_{4} {Z}_{4} ( ρ , ϕ ) + h ( r , ϕ ) > {A}_{E} {Z}_{4} ( ρ , ϕ ) .$$

The excess magnitude A_{E} can be empirically selected and can depend on the specific material used for the SCL.

Once the target paraboloid deformation Ã₄ has been determined, the thickness d of the SCL can be selected using a calibration data that tabulates or otherwise defines a function d=ƒ(Ã₄). In some embodiments, the function ƒ(Ã₄) can be a nonlinear function. In some embodiments, the function ƒ(Ã₄) can be a linear function, d=αÃ₄, with a coefficient of proportionality a determined based on mathematical modeling of elastic equations for specific SCL material(s), using empirical calibration, or any combination thereof. In some embodiments, thickness d of the SCL is selected to make deformation h_{corr}(r, ϕ) of a uniaxial type (e.g., cylindrical) after SCL deposition.

At block 460, the SCL of the selected thickness d (of a fixed thickness) can be deposited (or otherwise formed) on the substrate (e.g., as illustrated in FIG. 1E). The SCL can cause a reduction of deformation of the substrate. In some implementations, the SCL can formed using the same processing chamber as was used (e.g., at block 422) to form the feature protection layer. In some implementations, the feature protection layer and the SCL may include the same material, e.g., silicon nitride and/or the like. In some implementations, forming the SCL can include engaging the feature protection layer with an electrostatic chuck (e.g., to turn the substrate over or otherwise handle the substrate).

At block 470, method 400 can include covering the SCL with a protective film (e.g., cap layer 116 in in FIG. 1E). In some implementations, the protective film can include an oxide material (e.g., a silicon oxide material). In some implementations, forming the features (at block 420), the SCL (at block 460), and/or the SCL protection layer (at block 470) can be performed by physical substrate deposition, chemical substrate deposition, atomic layer deposition, photoresist spin coating, optical lithography, imprint lithography, digital lithography, contact photolithography, proximity photolithography, projection photolithography, and/or other suitable techniques. In some embodiments, the feature protection layer and the SCL can be formed using the same processing chamber. In some implementations, forming the SCL and covering the SCL layer with the protective film can also be performed the same processing chamber. In some embodiments, the feature protection layer and the SCL may be formed from (or include) the same material, e.g., silicon nitride. In some embodiments, forming the SCL can include engaging the feature protection layer with an electrostatic chuck.

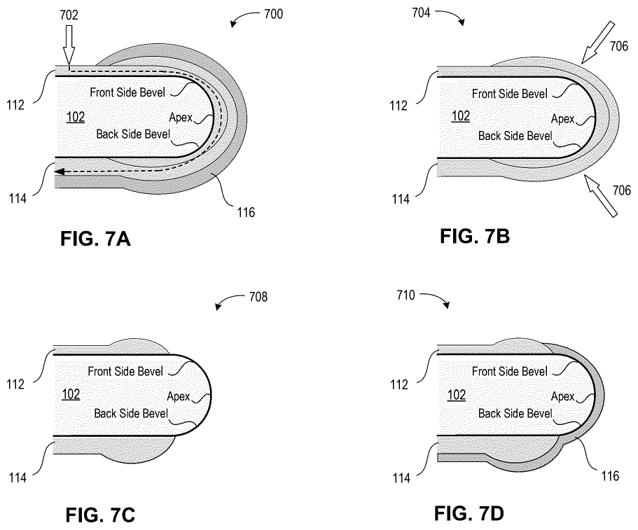

In some implementations, prior to covering the SCL with the protective film, operations of method 400 can include removing an edge region of each of the protective film and the SCL, e.g., as illustrated below in conjunction with FIG. 7.

At block 480, method 400 can continue with determining settings of the stress-mitigation beam using the optical inspection data. In some implementations, the settings for the stress-mitigation beam can include a type of particles of the stress-mitigation beam, an energy of the particles of the stress-mitigation beam, an angle of incidence of the particles of the stress-mitigation beam, and/or the like. Operations of block 480 can include determining (e.g., computing) local dose maps for irradiation of the SCL. In some embodiments, the dose maps can be computed in view on the expansion coefficients A₅, A₆ (to compensate for the saddle deformation) and A₇, A₈ . . . (to compensate for the residual deformation). At block 482, method 400 can continue with irradiating the SCL/directional pattern (e.g., according to the computed irradiation doses) with a stress-mitigation beam to reduce the amount of stress in the substrate/films/mask structure and flatten the structure (e.g., as illustrated in FIGS. 1E-1F). The stress-mitigation beam can include ions, photons, electrons, and/or any combination thereof.

At block 490, method 400 can include removing the feature protection layer and exhuming a portion, e.g., a subplurality of the features formed on the substrate, which can be performed via a single—unified—processing operation (e.g., performed in a single processing chamber). In some implementations, this processing operation can be performed by subjecting the feature protection layer and the subplurality of features to an acidic environment, e.g., a phosphoric acid environment. For example, the feature protection layer can be removed together with N layers of stack 104 (the outcome of such removal being illustrated in FIG. 1G). In some embodiments, prior to the removal of the subplurality of features, the SCL can be covered with a protective film, e.g., an oxide film (or a film that includes an oxide material).

Method 400 can further include various additional operations, as prescribed by a particular manufacturing specification, such as replacing the exhumed subplurality of features with one or more conducting materials (e.g., as illustrated in FIG. 1H), removing an excess of the conducting material (e.g., as illustrated in FIG. 1I), filling gaps with an insulating material (e.g., as illustrated in FIG. 1J), and/or, and/or performing any other suitable operations. In some implementations, the one or more conducting materials can include molybdenum, tungsten, and/or the like.

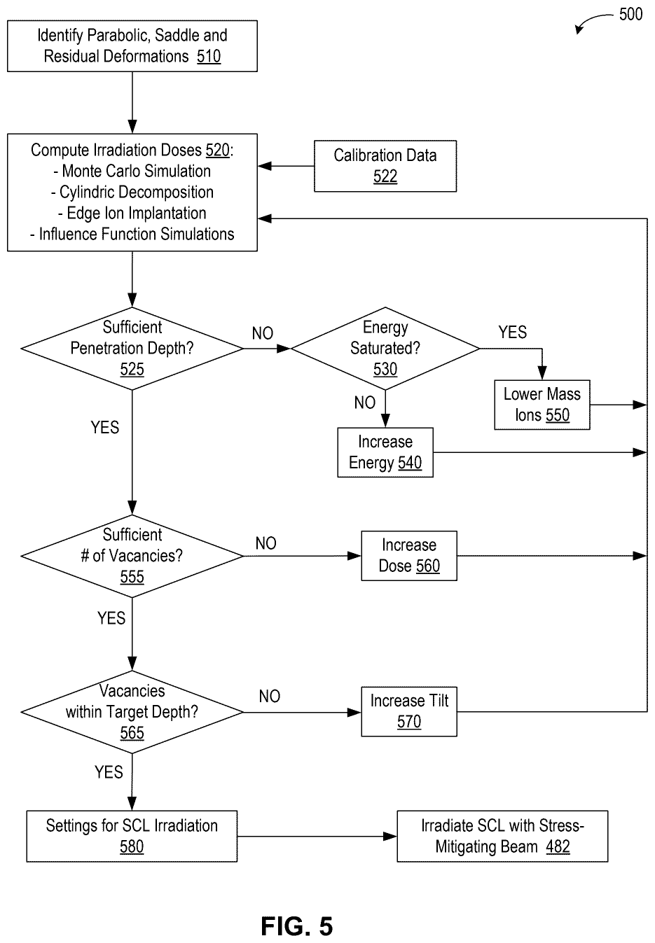

FIG. 5 is a flowchart illustrating an example method 500 of determining settings for beam irradiation, according to at least one embodiment. Method 500 can be performed as part of blocks 430-482 of method 400. At block 510, method 500 can include identifying some or all of a parabolic deformation (e.g., Zernike coefficients A₄), saddle deformation (e.g., Zernike coefficients A₅, A₆), and the residual deformation (e.g., Zernike coefficients A₇, A₈ . . . ) of a substrate, e.g., using profilometry measurements.

At block 520, method 500 can continue with computing irradiation doses n(\vec{r}) for the SCL deposited on the substrate. Operations of block 520 can include one or more techniques for determining n(\vec{r}). In some embodiments, irradiation doses n(\vec{r}) can be computed using Monte Carlo simulations. In some embodiments, irradiation doses n(\vec{r}) can be computed using cylindrical decomposition of h_{WF}(\vec{r}), e.g., a decomposition of a saddle shape deformation into a parabolic deformation and a cylindrical deformation.

In some embodiments, irradiation doses n(\vec{r}) can be computed (and then applied at block 595) for selected edge regions of the SCL. For example, if the axis of cylindrical deformation is the y-axis, the edge regions can be regions located within some vicinity of points x=±R, y=0, where R is the radius of the substrate. Irradiation doses n(\vec{r}) near other regions (e.g., near the center of the substrate) can be significantly lower and/or zero, in some embodiments. In some embodiments, the edge regions of the SCL have a width that is at or below 30% of a diameter of the substrate. In some embodiments, the edge regions of the SCL can be exposed to a spatially uniform dose of particles of the stress-mitigation beam, a radially-varying dose of particles of the stress-mitigation beam, or an azimuthally-varying dose of particles of the stress-mitigation beam. In some embodiments, irradiation doses n(\vec{r}) can be spread out more uniformly across the area of the substrate, e.g., can be non-zero both near the edges and near the middle of the substrate. In some embodiments, irradiation doses n(\vec{r}) can be uniform (constant) throughout the area of the substrate while the uniformity of stress-mitigation is achieved by the deposited protective pattern having spatially-varying parameters (e.g., width W, period P, thickness T, etc.).

In some embodiments, irradiation doses n(\vec{r}) can be computed using an influence function G(\vec{r}; \vec{r}′), also known as the Green's function, which characterizes a response (e.g., deformation) of the substrate at a point \vec{r} of the substrate as caused by a point-like force applied at a point \vec{r}′ of the substrate. In some embodiments, the influence function G(\vec{r}; \vec{r}′) can be determined from computational simulations or analytical calculations. In some embodiments, the influence function can be determined from one or more experiments, which can include performing ion implantation into a film deposited on a reference substrate. In some embodiments, a combination of multiple techniques of determining the influence function G(\vec{r}; \vec{r}′) can be used.

As a way of example, the Monte Carlo simulations for a structure (e.g., substrate with films and an SCL deposited thereon) can be performed for specific materials of the structure (e.g., silicon substrate, stack of films, and/or the like) and for a specific thickness of the structure. An initial Monte Carlo simulation can be performed for baseline (default) conditions of beam irradiation (e.g., default settings of an ion implantation apparatus or a light-emitting apparatus). The baseline conditions can include a default type of particles (ions, photons, electrons), a default energy of particles, a default dose of particles to be directed to the SCL (e.g., a default velocity of scanning and a default scanning pattern), and the like.

In some embodiments, various techniques of irradiation dose computations can use calibration data 522 collected for actual irradiation performed for various types of the irradiation beams, energies of the irradiation beams, types and materials of structures being irradiated, angles of beam incidence on the structures, and/or the like. In some embodiments, calibration data 522 can be statistically preprocessed. For example, various measurements can be collected for multiple substrate/films/SCL materials, types of particles, angles of incidence, and/or other parameters. The statistically processed measurements can be stored (e.g., in a memory of a processing device performing computation of the irradiation doses) in the form of probability distributions of various quantities, including but not limited to:
distribution of the density of ion implantation with depth for different ion types, ion energies, angles of incidence;
distribution of the number of vacancies produced at different depths (per unit of length of travel of the ions) for different types of irradiation particles (ions, photons, electrons), particle energies, and angles of incidence;
distribution of stresses created by irradiation beams for different beam intensities and durations; and/or the like.

Performing irradiation dose computations of block 520 can include sampling from the stored distributions and identifying a likelihood that a target stress mitigation will be achieved with the default settings of conditions of beam irradiation of a SCL of a given type and thickness. Method 500 can include several verification operations designed to determine whether the target stress can be achieved without detrimentally affecting properties of the substrate/films. For example, at block 525, method 500 can include verifying if the penetration depth of the selected (e.g., default) type of particles is sufficient. For example, the penetration depth is to be at least a certain fraction of the thickness of the SCL, e.g., 20%, 30%, 50%, 80%, or more of that thickness. In some embodiments the penetration depth can be up to 100% of the thickness. If the energy is insufficient, method 500 can include checking, at block 530, if the irradiation beam source is capable of outputting particles of a higher energy. If higher energies are available, method 500 can continue with increasing the energy of the particles (block 540) and repeating irradiation dose computations of block 520 for the increased energy. If the maximum energy of the irradiation beam source has already been reached, method 500 can continue with replacing (at block 550) ions with ions of a different type (e.g., if an ion beam is used for irradiation), e.g., replacing Silicon ions with Boron, Carbon, Fluorine, etc., ions, and repeating Monte Carlo simulations for the ions of the new type.

At block 555, method 500 can include verifying whether the number of expected formed vacancies is sufficient. To verify sufficiency, method 500 can assess stress mitigation caused by formed vacancies. In one embodiment, method 500 can begin at some value of stress in the SCL, e.g., −3.0 GPa or some other suitable value (negative sign indicating compressive stress) and use beam irradiation to mitigate this stress towards a neutral point, 0.0 GPa at various locales of the SCL.

If the number of vacancies is insufficient, method 500 can include increasing a dose of particles (at block 560) and repeating irradiation dose computations of block 520 for the increased dose.

At block 565, method 500 can include verifying that the vacancies are going to be placed within a target depth, e.g., the thickness d of the film or a certain fraction of the film, such as 0.8 d, 0.7 d, 0.5 d, or some other value empirically set to prevent particles from penetrating into the substrate/films and affecting properties of the substrate/films. If the vacancies are to be formed at depths that exceed the target depth, method 500 can include (at block 570) increasing an angle of incidence (e.g., by tilting the irradiation beam) to keep vacancies (as well as substitution impurities) to a shallower region of the SCL.

Blocks 520-570 can be repeated multiple times until irradiation dose computations of block 520 are determined to be sufficient that the desired stress mitigation can be achieved, e.g., that the reduction in the tensile stress of the SCL is such that the deformation of the substrate is eliminated or at least reduced to an acceptable tolerance. The final settings for SCL irradiation (block 580) determined from irradiation dose computations can then be used for irradiation of the SCL with the stress-mitigation beam (at block 482).

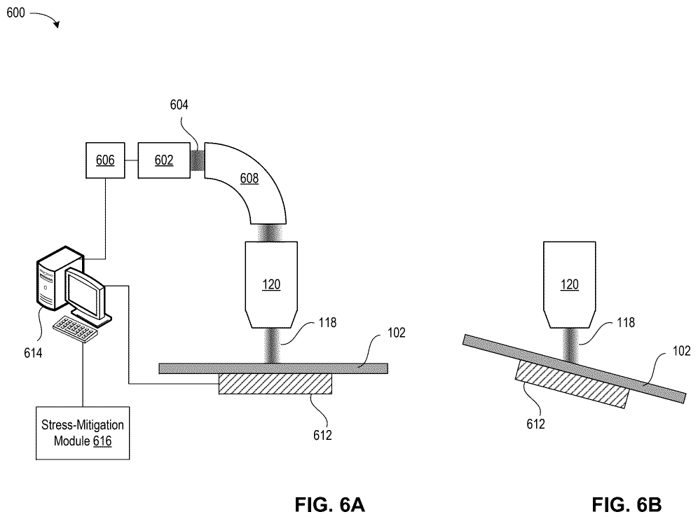

FIG. 6A illustrates schematically an irradiation system 600 capable of performing irradiation of stress compensation layers, according to at least one embodiment. Irradiation system 600 can include collimating and focusing column 120 of FIG. 1. Irradiation system 600 can further include a beam source 602 for producing a source beam 604. Beam source 602 can include a chamber for generating ions (e.g., a plasma chamber), a light source for generating photons (e.g., a laser, laser diode, lamp, etc.), a heated filament for producing electrons, and/or any other source for the particles of a type deployed in specific stress-mitigation techniques of the instant disclosure. Beam source 602 can be powered by a power element 606 and can include an extraction electrode assembly (not shown). Irradiation system 600 can include a mass spectrometer 608 (e.g., in the instances where beam source 602 produces charged particles, such as electrons or ions) and a collimating and focusing column 120. Collimating and focusing column 120 can direct stress-mitigation beam 118 to substrate 102. Substrate 102 can be supported by a support stage 612. In some embodiments, support stage 612 and substrate 102 can remain stationary during irradiation of substrate 102 by stress-mitigation beam 118 while components of irradiation system 600 can be repositioned relative to substrate 102. In some embodiments, irradiation system 600 can be stationary while support stage 612 can reposition substrate 102. In some embodiments, stress-mitigation beam 118 can have intensity (e.g., light intensity) that is modulated by changing intensity of beam source 602 and/or placing a partially absorbing or partially reflecting material at some location between beam source 602 and substrate 102. This enables delivery of local irradiation doses n(x, y) to various locations of substrate 102. Scanning with stress-mitigation beam 118 can occur along multiple directions, e.g., along x-axis and along y-axis according to any suitable predetermined pattern, e.g., back-and forth along x-axis, in a spiral pattern, and so on. In various embodiments, stress-mitigation beam 118 can be scanned with a frequency of several Hz, tens of Hz, hundreds of Hz, thousands of Hz, or more.

Operations of irradiation system 600 can be controlled by a controller 614, which can include any suitable computing device, microcontroller, or any other processing device having a processor, e.g., a central processing unit (CPU), a field-programmable gate array (FPGA), an application-specific integrated circuit (ASIC), and/or the like, and a memory device, e.g., a random-access memory (RAM), read-only memory (ROM), flash memory, and/or the like or any combination thereof. Controller 614 can control operations of power element 606, support stage 612, and/or various other components and modules of irradiation system 600. Controller 614 can include a stress-mitigation module 616 capable of performing simulations that determine a target intensity of stress-mitigation beam 118 to be used to mitigate various wafer deformations. In some embodiments, as illustrated in FIG. 6B, support stage 612 can impart a tilt, e.g., in one or two spatial directions to substrate 102 to change an angle of incidence of stress-mitigation beam 118 relative to substrate 102. In some embodiments, instead of tilting substrate 102, controller 614 can cause a tilt of stress-mitigation beam 118 relative to substrate 102.

FIGS. 7A-7D illustrate schematically handling of deposition of a front side protection layer and a back side stress-compensation layer near edges of substrates, according to at least one embodiment. Deposition of protection/stress-compensation layers near the edges of a substrate can be performed in a manner that protects and maintains integrity of the layers. FIG. 7A illustrates edge deposition 700 of front side protection layer 112 and back side SCL 114 near an edge of substrate 102, according to at least one embodiment. As illustrates, when front-side protection layer 112 is formed on the top surface of substrate 102, front-side protection layer 112 is wrapped around the edge of substrate 102 towards the back side of substrate 102. Similarly, when SCL 114 is formed on the back surface of substrate 102, SCL 114 is wrapped around the edge of substrate 102 (and previously formed front-side protection layer 112) towards the front side of substrate 102. A cap layer 116 can then be formed on the back side of substrate 102 to protect SCL 114 from external conditions. Cap layer 116 can also be wrapped around the edge of substrate 102, as shown. When front-side protection layer 112 is subsequently removed, e.g., by application of phosphoric acid or some other chemicals—as illustrated schematically with arrow 702—the chemicals removing front-side protection layer 112 (e.g., via a wet etch) can propagate around the edge, along the pathway depicted with the dashed arrow, to damage SCL 114. A number of techniques can be deployed to protect SCL 114 from such damage. In some implementations, front-side protection layer 112 and SCL 114 can be formed using different materials, with materials of SCL 114 being resistant to chemicals that etch front-side protection layer 112. This can prevent the chemicals from penetrating into SCL 114. FIGS. 7B-7D illustrate edge deposition with spatial separation of front-side deposition layer 112 and SCL 114. More specifically, as illustrated in FIG. 7B, after deposition 704 of front-side protection layer 112 and SCL 114 on substrate 102 (including wrapping around the edge of substrate 102), an edge portion of both front-side protection layer 112 and SCL 114 is removed, as indicated schematically with arrows 706. The removal of the edge portion can be performed, e.g., by local application of wet etch chemicals acting on the material of both layers. Both front-side layer 112 and SCL 114 can be made of the same material, e.g., silicon nitride, in one example. FIG. 7C illustrates an edge configuration 708 formed after the targeted removal of the edge portion, resulting in separation of front-side protection layer 112 and SCL 114 with the edge portion of both layers removed from the apex of the edge of substrate 102. FIG. 7D illustrates placement 710 of cap layer 116 (e.g., silicon dioxide or a similar cap layer) over SCL 114 and the edge of substrate 102. Correspondingly, when front-side protection layer 112 is removed, the wet etch chemicals do not have a path (as in FIG. 7A) to propagate to and damage SCL 114.

In some implementations, formation of spatially separated front-side protection layer 112 and SCL 114, as illustrated in FIG. 7C, can be achieved by placing an edge ring around substrate 102 such that a (narrow) front side bevel area and an apex area of substrate 102 are shielded from deposition material(s) when front-side protection layer 112 is being applied to the top surface of substrate 102. Similarly, during formation of SCL 114, the edge ring can be places around substrate 102 such that a back side bevel area and the apex area of substrate 102 are shield. The placed edge ring protects the edge of substrate 102 and ensures that the apex/bevel area of substrate 102 remains free from the material(s) of front-side protection layer 112 and SCL 114.

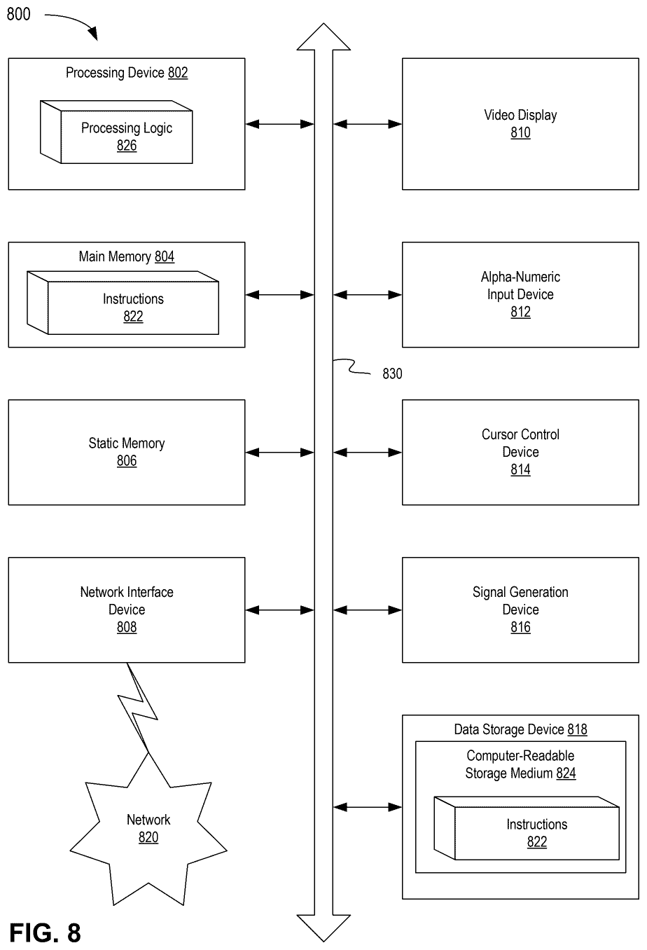

FIG. 8 depicts a block diagram of an example computer system 800 capable of supporting operations of the present disclosure, according to at least one embodiment. In various illustrative examples, example computer system 800 may be or include controller 614 of FIG. 6A. Example computer system 800 may be connected to other computer systems in a LAN, an intranet, an extranet, and/or the Internet. Computer system 800 may operate in the capacity of a server in a client-server network environment. Computer system 800 may be a personal computer (PC), a set-top box (STB), a server, a network router, switch or bridge, or any device capable of executing a set of instructions (sequential or otherwise) that specify actions to be taken by that device. Further, while only a single example computer system is illustrated, the term “computer” shall also be taken to include any collection of computers that individually or jointly execute a set (or multiple sets) of instructions to perform any one or more of the methods discussed herein.

Example computer system 800 may include a processing device 802 (also referred to as a processor or CPU), a main memory 804 (e.g., read-only memory (ROM), flash memory, dynamic random access memory (DRAM) such as synchronous DRAM (SDRAM), etc.), a static memory 806 (e.g., flash memory, static random access memory (SRAM), etc.), and a secondary memory (e.g., a data storage device 818), which may communicate with each other via a bus 830.

Processing device 802 represents one or more general-purpose processing devices such as a microprocessor, central processing unit, or the like. More particularly, processing device 802 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 802 may also be one or more special-purpose processing devices such as an application specific integrated circuit (ASIC), a field programmable gate array (FPGA), a digital signal processor (DSP), network processor, or the like. In accordance with one or more aspects of the present disclosure, processing device 802 may include a processing logic 826 configured to execute instructions (e.g., instructions 822) implementing example method 400 of mitigation of anisotropic wafer stress and deformation using stress-compensation beams and/or method 500 of determining settings for beam irradiation, in accordance with at least one embodiment.

Example computer system 800 may further comprise a network interface device 808, which may be communicatively coupled to a network 820. Example computer system 800 may further comprise a video display 810 (e.g., a liquid crystal display (LCD), a touch screen, or a cathode ray tube (CRT)), an alphanumeric input device 812 (e.g., a keyboard), a cursor control device 814 (e.g., a mouse), and an acoustic signal generation device 816 (e.g., a speaker).

Data storage device 818 may include a computer-readable storage medium (or, more specifically, a non-transitory computer-readable storage medium) 824 on which is stored one or more sets of executable instructions 822. In accordance with one or more aspects of the present disclosure, executable instructions 822 may comprise executable instructions implementing example method 400 of mitigation of anisotropic wafer stress and deformation using stress-compensation beams and/or method 500 of determining settings for beam irradiation, in accordance with at least one embodiment.

Executable instructions 822 may also reside, completely or at least partially, within main memory 804 and/or within processing device 802 during execution thereof by example computer system 800, main memory 804 and processing device 802 also constituting computer-readable storage media. Executable instructions 822 may further be transmitted or received over a network via network interface device 808.

While the computer-readable storage medium 824 is shown in FIG. 8 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “identifying,” “determining,” “storing,” “adjusting,” “causing,” “returning,” “comparing,” “creating,” “stopping,” “loading,” “copying,” “throwing,” “replacing,” “performing,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Examples of the present disclosure also relate to an apparatus for performing the methods described herein. This apparatus may be specially constructed for the required purposes, or it may be a general purpose computer system selectively programmed by a computer program stored in the computer system. Such a computer program may be stored in a computer readable storage medium, such as, but not limited to, any type of disk including optical disks, CD-ROMs, and magnetic-optical disks, read-only memories (ROMs), random access memories (RAMs), EPROMs, EEPROMs, magnetic disk storage media, optical storage media, flash memory devices, other type of machine-accessible storage media, or any type of media suitable for storing electronic instructions, each coupled to a computer system bus.

The methods and displays presented herein are not inherently related to any particular computer or other apparatus. Various general purpose systems may be used with programs in accordance with the teachings herein, or it may prove convenient to construct a more specialized apparatus to perform the required method steps. The required structure for a variety of these systems will appear as set forth in the description below. In addition, the scope of the present disclosure is not limited to any particular programming language. It will be appreciated that a variety of programming languages may be used to implement the teachings of the present disclosure.

It is to be understood that the above description is intended to be illustrative, and not restrictive. Many other embodiment examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

What is claimed is:

1. A method comprising:
covering a plurality of features on a front side of a substrate with a feature protection layer;
forming a stress-compensation layer (SCL) on a back side of the substrate, wherein the SCL causes a reduction of deformation of the substrate; and
removing, via a unified processing operation, the feature protection layer and a subplurality of features of the plurality of features.

2. The method of claim 1, wherein the plurality of features comprises:
a first set of layers comprising oxygen, and
a second set of layers comprising nitrogen, wherein the second set of layers is interspaced with the first set of layers.

3. The method of claim 1, wherein the plurality of features comprises:
a first set of layers comprising silicon, and
a second set of layers comprising a silicon-germanium alloy, wherein the second set of layers is interspaced with the first set of layers.

4. The method of claim 1, wherein the feature protection layer and the SCL are formed using a same processing chamber.

5. The method of claim 1, wherein the feature protection layer and the SCL comprise a same material.

6. The method of claim 5, wherein the same material comprises silicon nitride.

7. The method of claim 1, wherein forming the SCL comprises:
engaging the feature protection layer with an electrostatic chuck.

8. The method of claim 1, wherein removing the feature protection layer and the subplurality of features comprises:
exposing the feature protection layer and the subplurality of features to an acidic environment.

9. The method of claim 1, further comprising:
replacing the removed subplurality of features with one or more conducting materials.

10. The method of claim 9, wherein the one or more conducting materials comprise at least one of molybdenum or tungsten.

11. The method of claim 1, further comprising:
covering, prior to removing the subplurality of features, the SCL with a protective film.

12. The method of claim 11, wherein the protective film comprises an oxide material.

13. The method of claim 11, wherein forming the SCL and covering the SCL layer with the protective film are performed in a same processing chamber.

14. The method of claim 11, further comprises:
removing, prior to covering the SCL with the protective film, an edge region of each of the protective film and the SCL.

15. The method of claim 1, wherein forming the SCL comprises irradiating the SCL by a stress-mitigation beam comprising at least one of: a beam of ions, a beam of photons, or a beam of electrons.

16. The method of claim 15, wherein forming the SCL further comprises:
obtaining optical inspection data characterizing a profile of the deformation of the substrate; and
determining settings of the stress-mitigation beam using the optical inspection data.

17. The method of claim 16, wherein the settings for the stress-mitigation beam comprise one or more of:
a type of particles of the stress-mitigation beam,
an energy of the particles of the stress-mitigation beam, or
an angle of incidence of the particles of the stress-mitigation beam.

18. A method comprising:
covering a plurality of features on a front side of a substrate with a feature protection layer; and
forming a stress-compensation layer (SCL) on a back side of the substrate, wherein the SCL causes a reduction of deformation of the substrate, and wherein the feature protection layer and the SCL are formed using a same processing chamber.

19. The method of claim 18, further comprising:
removing, via a unified processing operation, the feature protection layer and a subplurality of features of the plurality of features.

20. A semiconductor manufacturing system comprising one or more processing chambers to:
cover a plurality of features on a front side of a substrate with a feature protection layer;
form a stress-compensation layer (SCL) on a bottom side of the substrate, wherein the SCL causes a reduction of deformation of the substrate; and
remove, via a unified processing operation, the feature protection layer and a subplurality of features of the plurality of features.
